(19) United States
(12) Patent Application Publication
(10) Pub. No.: US 2010/0193466 A1
(43) Pub. Date: Aug. 5, 2010

(54) METHOD OF MANUFACTURING CIRCUIT BOARD

(75) Inventors: Chih-Shueh Shih, Taoyuan County (TW); Chao-Hung Lo, Taoyuan County (TW); Jen-Hui Hsu, Taoyuan County (TW)

Correspondence Address: J C PATENTS, 4 VENTURE, SUITE 250, IRVINE, CA, 92618, US

(73) Assignee: UNIMICRON TECHNOLOGY CORP., Taoyuan (TW)

(21) Appl. No.: 12/411,219

(22) Filed: Mar. 25, 2009

(30) Foreign Application Priority Data
Feb. 4, 2009 (TW) 98103491

(51) Int. Cl. C23F 1/00; B05D 5/12; C23C 14/34; C25D 5/34

(52) U.S. Cl. 216/13; 427/97.2; 204/192.1; 205/205

(57) ABSTRACT

A method of manufacturing a circuit board is provided. Firstly, a substrate is provided, and a first conductive layer is disposed on the substrate. Next, a barrier layer is formed on the first conductive layer. Thereafter, a through hole passing through the substrate, the first conductive layer, and the barrier layer is formed. A second conductive layer including a conductive rod disposed in the through hole is formed on an inside wall of the through hole and the barrier layer. After that, parts of the second conductive layer located outside the through hole are removed. Next, the barrier layer is removed, and a circuit layer is formed on the first conductive layer and the conductive rod. Parts of the first conductive layer exposed by the circuit layer are then removed.

### CROSS-REFERENCE TO RELATED APPLICATION

This application claims the priority benefit of Taiwan application serial no. 98103491, filed on Feb. 4, 2009. The entirety of the above-mentioned patent application is hereby incorporated by reference herein and made a part of specification.

### BACKGROUND OF THE INVENTION

1. Field of the Invention

The present invention relates to a method of manufacturing a circuit board. More particularly, the present invention relates to a method of manufacturing a circuit board capable of achieving favorable electrical connection quality between an electric device and the circuit board.

2. Description of Related Art

With the progress in technologies, electronic products including cellular phones, notebook PCs, and personal digital assistants (PDAs) have been extensively applied in modern society. Among components in the electronic products, not only electric devices comprising chips and passive components are required, but also a circuit board for carrying and disposing the chips and the passive components are also indispensable.

Based on actual demands, a single circuit layer or multiple circuit layers can be disposed in the circuit board. When multiple circuit layers are contained in the circuit board, the circuit layers are electrically connected to one another through a plurality of plating through holes. Here, the plating through holes are formed by covering an inside wall of through holes of the circuit board with a conductive through hole layer which connects at least two circuit layers. In addition, the multiple circuit layers of the circuit board can be electrically connected to one another through conductive rods disposed in the through holes, so as to meet recent requirements for transmitting signals with high frequency or dissipating heat.

FIGS. 1A through 1D are cross-sectional views illustrating a process of manufacturing a conventional circuit board. First, referring to FIG. 1A, a substrate 110 and two conductive layers 122 and 124 respectively disposed on an upper surface and a bottom surface of the substrate 110 are provided. Next, a through hole T is formed on the substrate 110 and the conductive layers 122 and 124. Thereafter, referring to FIG. 1B, a conductive layer 130 is formed on the conductive layers 122 and 124 and an inside wall T1 of the through hole T. After that, a patterned mask layer 140 is formed on the conductive layer 130.

Referring to FIG. 1C, an electroplating step is then performed to form a conductive layer 150 on the conductive layer 130 exposed by the patterned mask layer 140. The conductive layer 150 has a conductive rod 152 disposed in the through hole T and a circuit layer 154 filling openings OP of the patterned mask layer 140. Next, referring to FIG. 1D, the patterned mask layer 140 and parts of the conductive layers 122, 124, and 130 located below the patterned mask layer 140 are removed.

It can be learned from the above that the conductive rod 152 and the circuit layer 154 are simultaneously formed by performing one electroplating step in the process of manufacturing the conventional circuit board. Nonetheless, size of the through hole T and size of the openings OP are rather different, and therefore it is not apt to control the electroplating step simultaneously implemented in the through hole T and the openings OP. As such, it is very likely for the circuit layer 154 to be equipped with a surface 154a which is not flattened, giving rise to unfavorable electrical connection quality between the electric device and the circuit board.

### SUMMARY OF THE INVENTION

The present invention is directed to a method of manufacturing a circuit board. By applying said method, the circuit board having a conductive rod can be formed, and a circuit layer of the circuit board has a flattened surface.

In the present invention, a method of manufacturing a circuit board is provided below. Firstly, a substrate is provided, and a first conductive layer is disposed on the substrate. Next, a first barrier layer is formed on the first conductive layer. Thereafter, a through hole passing through the substrate, the first conductive layer, and the first barrier layer is formed. A second conductive layer is then formed on an inside wall of the through hole and the first barrier layer. The second conductive layer includes a conductive rod disposed in the through hole. After that, parts of the second conductive layer located outside the through hole are removed. The first barrier layer is then removed. Afterwards, a first circuit layer is formed on the first conductive layer and an end of the conductive rod. Next, parts of the first conductive layer exposed by the first circuit layer are removed.

According to an embodiment of the present invention, a third conductive layer is further disposed on a surface of the substrate away from the first conductive layer. Besides, the method of manufacturing the circuit board further includes following steps. During formation of the first barrier layer, a second barrier layer is formed on the third conductive layer. Here, the through hole further passes through the third conductive layer and the second barrier layer, and the second conductive layer further covers the second barrier layer. Next, during removal of the first barrier layer, the second barrier layer is removed. Thereafter, during formation of the first circuit layer, a second circuit layer is formed on the third conductive layer and the other end of the conductive rod. After that, parts of the third conductive layer exposed by the second circuit layer are removed during removal of the parts of the first conductive layer exposed by the first circuit layer.

According to an embodiment of the present invention, a material of the first barrier layer is different from a material of the first conductive layer and a material of the second conductive layer.

According to an embodiment of the present invention, a method of forming the first barrier layer includes sputtering or chemical deposition.

According to an embodiment of the present invention, a material of the first barrier layer includes nickel, tin, aluminum, chromium, or zinc.

According to an embodiment of the present invention, a method of forming the through hole includes mechanical drilling.

According to an embodiment of the present invention, a method of forming the second conductive layer includes electroplating.

According to an embodiment of the present invention, a method of removing the parts of the second conductive layer located outside the through hole includes etching.

According to an embodiment of the present invention, a method of forming the first circuit layer includes following steps. First, a patterned mask layer is formed on the first conductive layer. Next, the first circuit layer is formed on the conductive rod and parts of the first conductive layer exposed by the patterned mask layer. The patterned mask layer is then removed.

According to an embodiment of the present invention, a method of removing the parts of the first conductive layer exposed by the first circuit layer includes etching.

According to an embodiment of the present invention, the method of manufacturing the circuit board further includes forming a fourth conductive layer on the inside wall of the through hole and the first barrier layer before the second conductive layer is formed. Besides, the second conductive layer is formed on the fourth conductive layer.

Based on the above, the barrier layer is used to separate the process of forming the conductive rod from the process of forming the circuit layers in the present invention, such that the conductive rod and the circuit layers are individually formed without affecting each other. Further, the circuit layers can be equipped with flattened surfaces. Hence, favorable electrical connection quality between the circuit layers and the electric device can be accomplished in the present invention.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A through 1D are cross-sectional views illustrating a process of manufacturing a conventional circuit board.

FIG. 2A through 2H illustrate a method of manufacturing a circuit board.

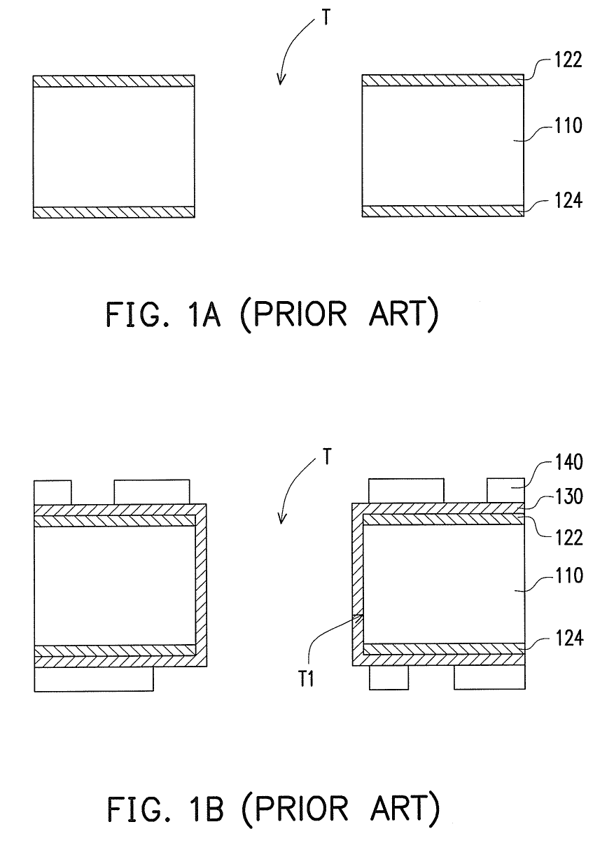

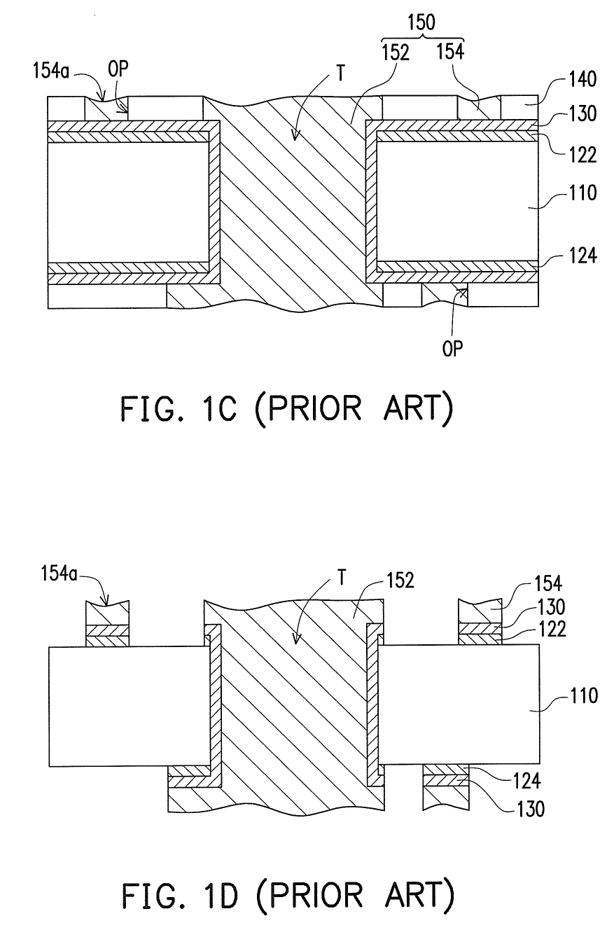

### DESCRIPTION OF EMBODIMENTS

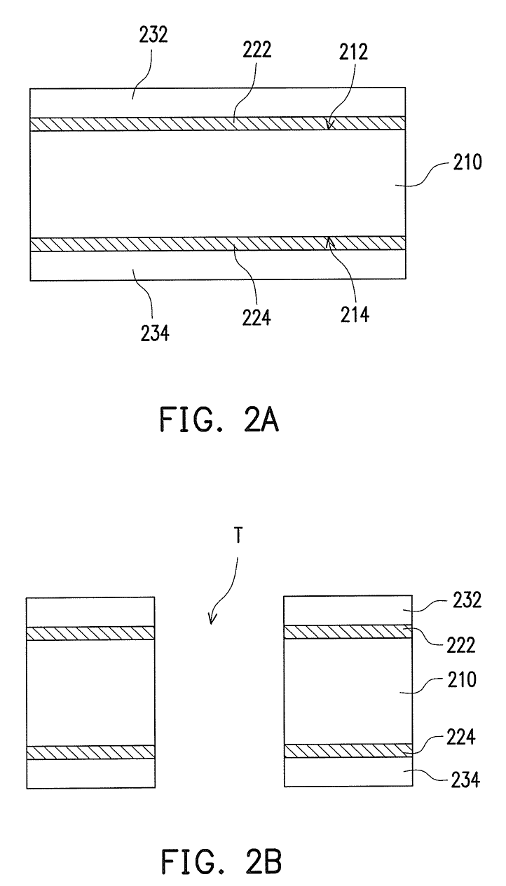

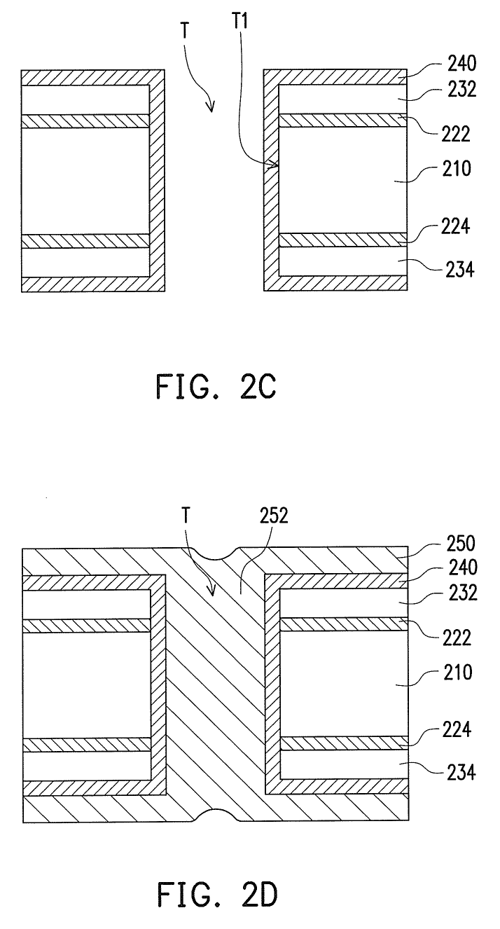

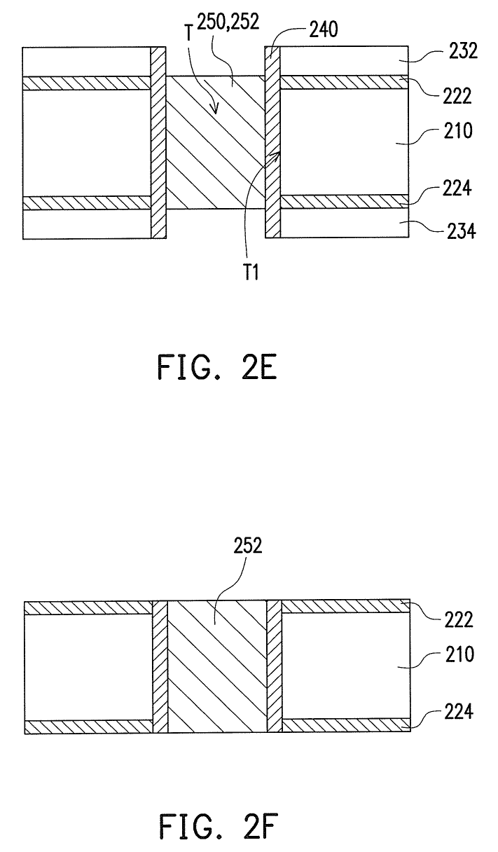

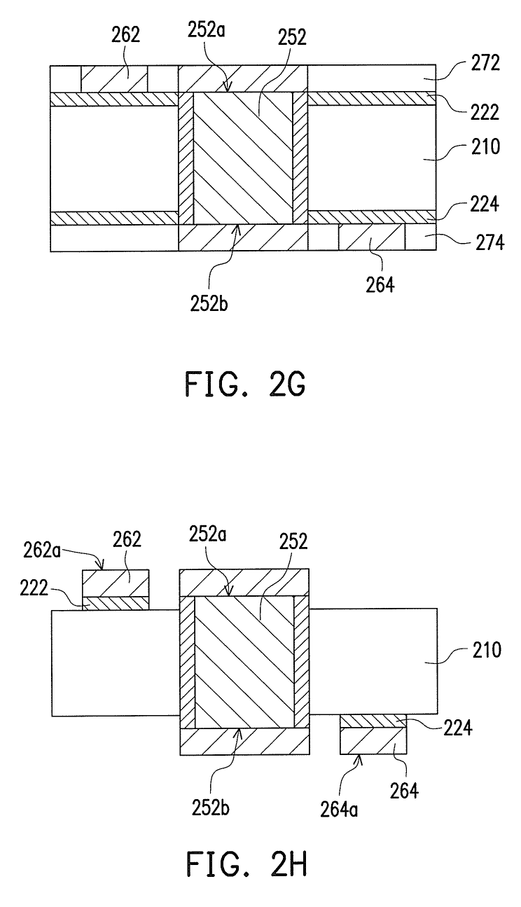

FIG. 2A through 2H illustrate a method of manufacturing a circuit board as described below.

First, referring to FIG. 2A, a substrate 210 is provided. The substrate 210 is, for example, a dielectric substrate or a multi-layered board. A conductive layer 222 and a conductive layer 224 are respectively disposed on two opposite surfaces 212 and 214 of the substrate 210. The conductive layers 222 and 224 are made of materials characterized by satisfactory conductivity, such as copper, etc. The substrate 210 and the conductive layers 222 and 224 can all be referred to as a copper clad laminate (CCL).

Next, a barrier layer 232 and a barrier layer 234 are respectively formed on the conductive layer 222 and the conductive layer 224, and a method of forming the barrier layers 232 and 234 is, for example, sputtering or chemical deposition. A material of the barrier layers 232 and 234 is, for example, nickel, chromium, tin, aluminum, zinc, or any other appropriate material. In the present embodiment, a material of the barrier layers 232 and 234 is different from a material of the conductive layers 222 and 224. Therefore, an etching solution suitable for etching the conductive layers 222 and 224 is different from an etching solution suitable for etching the barrier layers 232 and 234. As such, either the barrier layers 232 and 234 or the conductive layers 222 and 224 can be selectively etched according to the present embodiment.

Thereafter, referring to FIG. 2B, a through hole T passing through the substrate 210, the conductive layers 222 and 224, and the barrier layers 232 and 234 is formed. Here, a method of forming the through hole T is, for example, mechanical drilling. After that, referring to FIG. 2C, a conductive layer 240 is formed on an inside wall T1 of the through hole T and the barrier layers 232 and 234. Here, a material of the conductive layer 240 is characterized by favorable conductivity, such as copper, etc.

Referring to FIG. 2D, a conductive layer 250 is then formed on the conductive layer 240 by performing an electroplating process, for example. Here, the conductive layer 250 includes a conductive rod 252 disposed in the through hole T. Note that a material of the conductive layers 240 and 250 is different from the material of the barrier layers 232 and 234. Therefore, an etching solution suitable for etching the conductive layers 240 and 250 is different from the etching solution suitable for etching the barrier layers 232 and 234. As such, either the barrier layers 232 and 234 or the conductive layers 240 and 250 can be selectively etched according to the present embodiment.

Afterwards, referring to FIG. 2E, parts of the conductive layers 240 and 250 located outside the through hole T are removed by performing an etching process, for example, and parts of the conductive layer 240 located on the inside wall T1 of the through hole T and the conductive rod 252 of the conductive layer 250 are left. To be more specific, an etching solution suitable for etching the conductive layers 240 and 250 is employed in the present embodiment to etch the conductive layers 240 and 250 until the barrier layers 232 and 234 are exposed. That is to say, the barrier layers 232 and 234 serve as etching stop layers of the aforesaid etching process.

Next, as indicated in FIG. 2F, the barrier layers 232 and 234 are removed by performing an etching process, for example. Particularly, for instance, an etching solution suitable for etching the barrier layers 232 and 234 is employed in the present embodiment to remove the barrier layers 232 and 234 until the conductive layers 222 and 224 are exposed. Namely, the conductive layers 222 and 224 serve as etching stop layers of the aforesaid etching process.

Referring to FIG. 2G, two patterned mask layers 272 and 274 are then formed on the conductive layers 222 and 224, respectively. Thereafter, a circuit layer 262 is formed on parts of the conductive layer 222 exposed by the patterned mask layer 272 and on an end 252a of the conductive rod 252, and a circuit layer 264 is formed on parts of the conductive layer 224 exposed by the patterned mask layer 274 and on the other end 252b of the conductive rod 252.

After that, referring to FIG. 2H, the patterned mask layers 272 and 274 are removed. Parts of the conductive layer 222 exposed by the circuit layer 262 and parts of the conductive layer 224 exposed by the circuit layer 264 are then removed by, for example, performing an etching process.

It should be mentioned that the conductive rod 252 and the circuit layers 262 and 264 are formed in two separate steps according to the present embodiment. Thereby, the circuit layers 262 and 264 can be equipped with flattened surfaces 262a and 264a, respectively. Moreover, electrical connection quality between the circuit layers 262 and 264 and an electric device (not shown) can be improved.

In view of the foregoing, the barrier layers are used to separate the process of forming the conductive rod from the process of forming the circuit layers in the present invention, such that the conductive rod and the circuit layers are individually formed without affecting each other. Further, the circuit layers can be equipped with flattened surfaces. Hence, favorable electrical connection quality between the circuit layers and the electric device can be accomplished in the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a circuit board, comprising:
providing a substrate, a first conductive layer being disposed on the substrate;
forming a first barrier layer on the first conductive layer;
forming a through hole passing through the substrate, the first conductive layer, and the first barrier layer;
forming a second conductive layer on an inside wall of the through hole and the first barrier layer, the second conductive layer comprising a conductive rod disposed in the through hole;
removing parts of the second conductive layer located outside the through hole;
removing the first barrier layer;
forming a first circuit layer on the first conductive layer and an end of the conductive rod; and
removing parts of the first conductive layer exposed by the first circuit layer.

2. The method of manufacturing the circuit board as claimed in claim 1, wherein a third conductive layer is further disposed on a surface of the substrate away from the first conductive layer, and the method of manufacturing the circuit board further comprises:
forming a second barrier layer on the third conductive layer during formation of the first barrier layer, wherein the through hole further passes through the third conductive layer and the second barrier layer, and the second conductive layer further covers the second barrier layer;
removing the second barrier layer during removal of the first barrier layer;
forming a second circuit layer on the third conductive layer and the other end of the conductive rod during formation of the first circuit layer; and
removing parts of the third conductive layer exposed by the second circuit layer during removal of the parts of the first conductive layer exposed by the first circuit layer.

3. The method of manufacturing the circuit board as claimed in claim 2, further comprising:
forming a fourth conductive layer on the inside wall of the through hole and the first barrier layer before the second conductive layer is formed, the second conductive layer being formed on the fourth conductive layer.

4. The method of manufacturing the circuit board as claimed in claim 1, wherein a material of the first barrier layer is different from a material of the first conductive layer and a material of the second conductive layer.

5. The method of manufacturing the circuit board as claimed in claim 1, wherein a method of forming the first barrier layer comprises sputtering or chemical deposition.

6. The method of manufacturing the circuit board as claimed in claim 1, wherein a material of the first barrier layer comprises nickel, chromium, tin, aluminum, or zinc.

7. The method of manufacturing the circuit board as claimed in claim 1, wherein a method of forming the through hole comprises mechanical drilling.

8. The method of manufacturing the circuit board as claimed in claim 1, wherein a method of forming the second conductive layer comprises electroplating.

9. The method of manufacturing the circuit board as claimed in claim 1, wherein a method of removing the parts of the second conductive layer located outside the through hole comprises etching.

10. The method of manufacturing the circuit board as claimed in claim 1, wherein a method of forming the first circuit layer comprises:
forming a patterned mask layer on the first conductive layer;
forming the first circuit layer on the conductive rod and parts of the first conductive layer exposed by the patterned mask layer; and
removing the patterned mask layer.

11. The method of manufacturing the circuit board as claimed in claim 1, wherein a method of removing the parts of the first conductive layer exposed by the first circuit layer comprises etching.

12. The method of manufacturing the circuit board as claimed in claim 1, further comprising:
forming a fourth conductive layer on the inside wall of the through hole and the first barrier layer before the second conductive layer is formed, the second conductive layer being formed on the fourth conductive layer.
